(19) United States
(12) Patent Application Publication
(10) Pub. No.: US 2009/0033386 A1
(43) Pub. Date: Feb. 5, 2009

(54) Delay Lock Loop Circuits Including Glitch Reduction and Methods for Using Such

(75) Inventors: Padattil K. Nisha, Bangalore (IN); Keerthinarayan P. Heragu, Richardson, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 11/832,030

(22) Filed: Aug. 1, 2007

(51) Int. Cl. H03L 7/06

(52) U.S. Cl. 327/158

(57) ABSTRACT

Various systems and methods for delaying one signal in relation to another are disclosed. As one example, a delay lock loop circuit is discussed that includes at least a first delay stage and a second delay stage, each including a plurality of selectable delay elements. The delay stages are configured such that a gated reference signal drives an input of the first delay stage, and a first output from the first delay stage drives an input of the second delay stage. The circuits further include a unified selector register that is associated with both the first delay stage and the second delay stage. A value maintained in the unified selector register determines a number of the selectable delay elements utilized in the first delay stage and a number of the selectable delay elements utilized in the second delay stage. In operation, modification of the value maintained in the unified selector register is synchronized to the reference signal. A reference signal gate is included that receives the reference signal and provides the gated reference signal. The gated reference signal is substantially the reference signal modified such that the gated reference signal is not asserted when modification of the unified selector register is enabled.

### BACKGROUND OF THE INVENTION

The present invention is related to event synchronization, and more particularly to systems and methods for synchronizing one signal to another signal in a semiconductor device.

Synchronizing one electrical signal to another often involves applying the signal to a data input of a flip-flop, and clocking the flip-flop using a clock to which the signal is to be synchronized. The signal to be synchronized generally must be applied to the data input of the flip-flop for a defined period before the clock transitions (i.e., setup time), and must remain for a defined period after the clock transitions (i.e., hold time). By assuring that the setup and hold times are met, predictable circuit operation is achieved.

In some cases, a delay lock loop circuit has been used to delay a signal in relation to a synchronizing clock to assure that setup and hold times are met. Such delay lock loops may be iteratively updated until a desired delay is achieved. Various implementations of delay lock loop circuits, however, may incur clock glitches when an iterative update is occurring. Such glitches can at time lead to circuit errors.

Thus, for at least the aforementioned reasons, there exists a need in the art for advanced systems and devices for signal synchronization.

### BRIEF SUMMARY OF THE INVENTION

The present invention is related to event synchronization, and more particularly to systems and methods for synchronizing one signal to another signal in a semiconductor device.

Various embodiments of the present invention provide delay lock loop circuits that receive a reference signal. Such delay lock loop circuits include at least a first delay stage and a second delay stage. Each of the aforementioned delay stages includes a plurality of selectable delay elements. The delay stages are configured such that a gated reference signal drives an input of the first delay stage, and a first output from the first delay stage drives an input of the second delay stage. The circuits further include a unified selector register that is associated with both the first delay stage and the second delay stage. A value maintained in the unified selector register determines a number of the selectable delay elements utilized in the first delay stage and a number of the selectable delay elements utilized in the second delay stage. In operation, modification of the value maintained in the unified selector register is synchronized to the reference signal. A reference signal gate is included that receives the reference signal and provides the gated reference signal. The gated reference signal is substantially the reference signal modified such that the gated reference signal is not asserted when modification of the unified selector register is enabled.

In some instances of the aforementioned embodiments, the circuits further include a counter circuit that is synchronized to the reference signal. In such instances, the counter circuit periodically asserts an enable signal that enables modification of the unified selector register. In some such cases, the reference signal gate gates the reference signal whenever the enable signal is asserted. In one or more instances of the aforementioned embodiments, the first delay stage and the second delay stage are substantially identical. In particular instances of the aforementioned embodiments, the plurality of delay elements are a plurality of single input buffers, a plurality of multiple input logic gates, or a combination thereof.

In various instances of the aforementioned embodiments, the circuits further include a third, fourth and fifth delay stage. Each of the aforementioned delay stages includes the plurality of selectable delay elements. The third delay stage provides a third output, the fourth delay stage provides a fourth output, and the fifth delay stage provides a fifth output. The second output drives an input of the third delay stage, the third output drives an input of the fourth delay stage, and the fourth output drives an input of the fifth delay stage. In such cases, the unified selector register is additionally associated with each of the third, fourth and fifth delay stages; and the value maintained in the unified selector register determines a number of the selectable delay elements utilized in the third, fourth and fifth delay stages. In some such cases, the circuits further include a feedback loop where two or more of the reference signal or gated reference signal and stage outputs are compared. Based on the comparison, the feedback loop is operable to determine the value maintained in the unified selector register.

Other embodiments of the present invention provide methods for glitch reduction in a delay lock loop circuit. Such methods include receiving a reference signal, and providing a delay lock loop circuit. The delay lock loop circuit includes at least a first delay stage and a second delay stage. Each of the first delay stage and the second delay stage includes a plurality of selectable delay elements. A gated reference signal drives an input of the first delay stage that in turn provides a first output. The first output drives an input of the second delay stage that in turn provides a second output. The delay lock loop circuit further includes a unified selector register associated with both the first delay stage and the second delay stage. A value maintained in the unified selector register determines a number of the selectable delay elements utilized in the first delay stage and a number of the selectable delay elements utilized in the second delay stage. The methods further include periodically asserting an enable signal that enables modification of the unified selector register, and modifying the value maintained in the unified selector register. Modifying the value maintained in the unified selector register results in a modification of the number of the selectable delay elements utilized in the first delay stage and the number of the selectable delay elements utilized in the second delay stage. The method further includes gating the reference signal whenever the enable signal is asserted to produce the gated reference signal.

This summary provides only a general outline of some embodiments according to the present invention. Many other objects, features, advantages and other embodiments of the present invention will become more fully apparent from the following detailed description, the appended claims and the accompanying drawings.

### BRIEF DESCRIPTION OF THE DRAWINGS

A further understanding of the various embodiments of the present invention may be realized by reference to the figures which are described in remaining portions of the specification. In the figures, like reference numerals are used throughout several drawings to refer to similar components. In some instances, a sub-label consisting of a lower case letter is associated with a reference numeral to denote one of multiple similar components. When reference is made to a reference numeral without specification to an existing sub-label, it is intended to refer to all such multiple similar components.

FIG. 1a shows a memory system that utilizes a combination memory controller and delay lock loop circuit in accordance with one or more embodiments of the present invention;

FIG. 1b depicts a strobe signal delayed in relation to a data signal;

FIGS. 2a-2e show a delay lock loop circuit including glitch reduction circuitry in accordance with some embodiments of the present invention;

FIG. 3 depicts a slave delay stage along with an interface circuit to the slave delay stage that may be implemented in relation to various embodiments of the present invention; and

FIG. 4 is a flow diagram depicting a method in accordance with one or more embodiments of the present invention for glitch free operation of a delay lock loop circuit.

### DETAILED DESCRIPTION OF THE INVENTION

The present invention is related to event synchronization, and more particularly to systems and methods for synchronizing one signal to another signal in a semiconductor device.

Various embodiments of the present invention provide delay lock loop circuits and methods for using such. As one example, a delay lock loop circuit is provided that includes at least a first delay stage and a second delay stage. As used herein, the phrase “delay stage” is used in its broadest sense to mean any combination of circuitry that is capable of delaying one signal relative to another. Thus, for example, a delay stage may receive a reference signal and provide a derivative of the reference signal that is shifted in time by a particular delay. Each of the aforementioned delay stages includes a plurality of selectable delay elements. As used herein, the phrase “plurality of selectable delay elements” is used in its broadest sense to mean two or more delay introducing circuits or circuit elements that each may be selected into a set of delay elements that together provide a particular delay.

The delay stages may be configured such that a gated reference signal drives an input of the first delay stage, and a first output from the first delay stage drives an input of the second delay stage. The circuits further include a unified selector register that is associated with both the first delay stage and the second delay stage. As used herein, the phrase “selector register” is used in its broadest sense to mean any storage circuit that is capable of maintaining a value. Further, as used herein, the phrase “unified selector register” is used to imply that the value maintained in the selector register is provided to two or more delay stages. In a particular instance, the value maintained in the unified selector register determines a number of the selectable delay elements utilized in the first delay stage and a number of the selectable delay elements utilized in the second delay stage. In operation of the aforementioned circuits, modification of the value maintained in the unified selector register is synchronized to the reference signal. A reference signal gate is included that receives the reference signal and provides the gated reference signal. As used herein, the phrase “reference signal gate” is used in its broadest sense to mean any circuit that is capable of applying a gating function to an input signal, and to provide a gated output signal. The gated reference signal is substantially the reference signal modified such that the gated reference signal is not asserted when modification of the unified selector register is enabled.

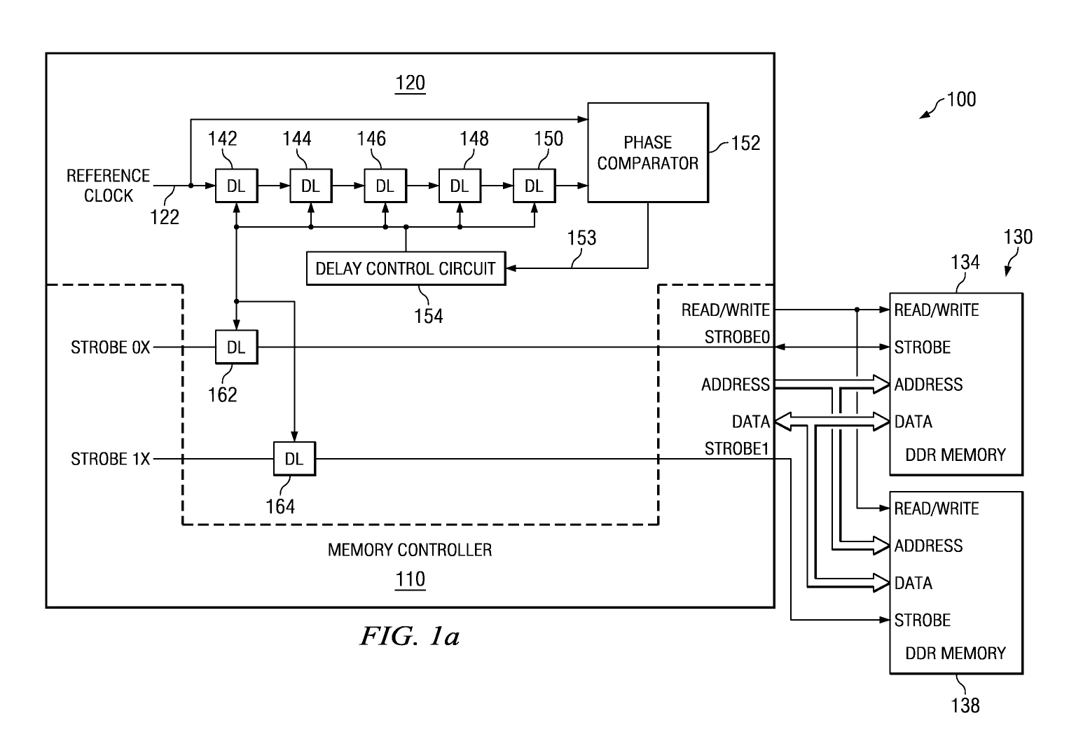

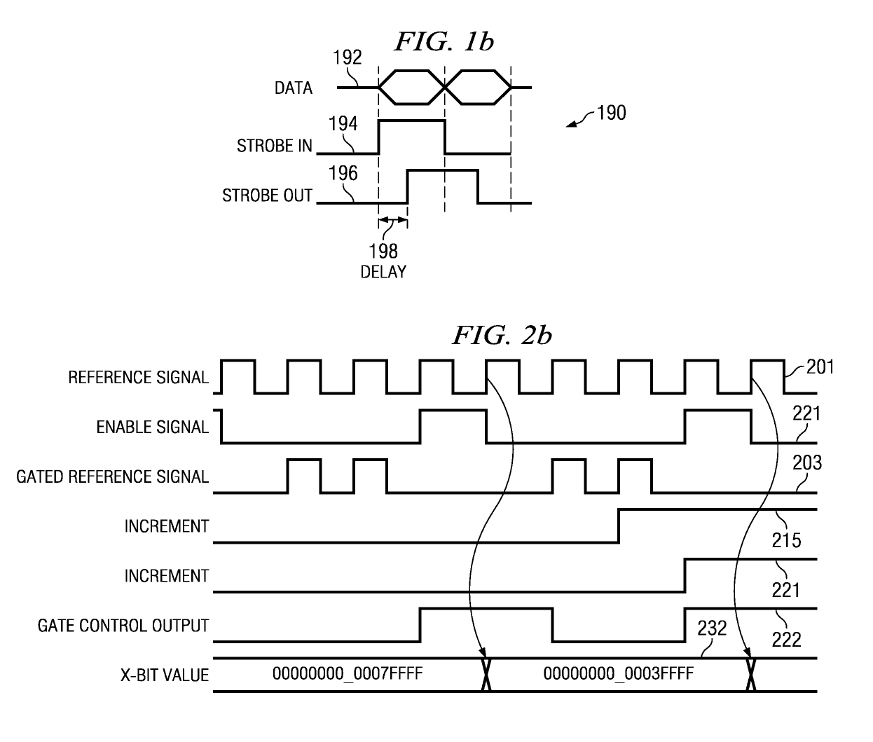

Turning to FIG. 1a, a memory system 100 is shown that utilizes a combination memory controller 110 and a delay lock loop circuit 120 in accordance with one or more embodiments of the present invention. It should be noted that delay lock loop circuit 120 may be implemented on the same semiconductor die as memory controller 110, or may be implemented on a different die. Further, it should be noted that delay lock loop circuit 120 may be integrated with memory controller 110 or may be implemented as separate modules of the same circuit design. As shown, memory controller 110 includes a number of signals that are generated to allow access to one or more memory modules. Generation of such signals may be accomplished in various ways as are known in the art. For example, the same strobe signal may be used for both read and write signals, or a strobe signal for the read and a strobe signal for the write may be created internal to memory controller 110 and only at the interface of memory controller 110 are the two signals combined to drive the strobe I/O of the external memory. As shown, memory system 100 includes a bank 130 of double data rate memory blocks 134, 138. It should be noted that other memory types may be used in accordance with different embodiments of the present invention. Each of memory blocks 134, 138 includes an interface consisting of an address bus, a data bus, a strobe and a read/write control line. In operation, when data is to be written to memory block 134, the appropriate address is applied to the address bus, the read/write control line is asserted to indicate a write operation, data is placed on the data bus, and the strobe signal for memory block 134 (i.e., strobe 0) is asserted. The same process is done to write data to memory block 138, except that the strobe signal for memory block 138 (i.e., strobe 1) is asserted. In contrast, when data is to be read from memory block 134, the appropriate address is applied to the address bus, the read/write control line is asserted to indicate a read operation. Memory block 134 then asserts the strobe associated memory block 134 (i.e., strobe 0) coincident with applying data to the data bus. The same process is used for reading data from memory block 138, except that the strobe associated with memory block 138 is asserted. Based on the disclosure provided herein, one of ordinary skill in the art will recognize a variety of interfaces or signal sets that may be used in accordance with different embodiments of the present invention.

In some cases, the strobe and the data are not properly aligned during the read and write cycles. In such cases, delay lock loop circuit 120 may be used to delay one or more strobe signals to create the appropriate alignment. As shown, a delay stage 162 is used to delay the strobe associated with memory block 134, and a delay stage 164 is used to delay the strobe associated with memory block 138. It should be noted that depending upon the configuration, delay stage 162 may be designed to delay a strobe received from memory block 134 by a particular amount, or delay stage 162 may be designed to delay a strobe provided to memory block 134 from memory controller 110. Similarly, depending upon the configuration, delay stage 164 may be designed to delay a strobe received from memory block 138 by a particular amount, or delay stage 164 may be designed to delay a strobe provided to memory block 138 from memory controller 110. The amount of delay applied by delay stage 162 and delay stage 164 is controlled by delay lock loop circuit 120. It should be noted that delay lock loop circuit 120 may be implemented in relation to a circuit other than a memory controller. Based on the disclosure provided herein, one of ordinary skill in the art will recognize a variety of applications that may benefit from use of such a delay lock loop circuit.

The aforementioned process of delaying strobes using delay stages 162, 164 is graphically displayed in FIG. 1b. Turning to FIG. 1b, a timing diagram 190 shows data 192 applied to the aforementioned data bus and a corresponding strobe in 194. As shown, strobe in 194 transitions coincident with the change in data 192. In some cases such an immediate transition results in a setup or hold problem in either memory blocks 134, 138 or a device receiving data from memory blocks 134, 138. By introducing a controlled time delay 198 to strobe in 194, any setup or hold problems may be averted. As more fully discussed below, time delay 198 is programmable by selecting a different number of delay elements implemented as part of delay stages 162, 164.

The number of delay elements utilized in delay stages 162, 164 is determined through delay locking to a reference clock 122 using delay lock loop circuit 120. Delay lock loop circuit 120 includes a delay stage 142, a delay stage 144, a delay stage 146, a delay stage 148 and a delay stage 150. In some instances, all of delay stages 142, 144, 146, 148, 150 are substantially identical including the same number of delay elements. As shown, reference clock 122 is an input to delay stage 142, the output of delay stage 142 is the input of delay stage 144, the output of delay stage 144 is the input of delay stage 146, the output of delay stage 146 is the input of delay stage 148, and the output of delay stage 148 is the input of delay stage 150.

The output of delay stage 150 (or in some cases, an output of one of the other delay stages 142, 144, 146, 148) is compared with reference clock 122 by a phase comparator 152. The output of phase comparator 152 indicates whether the number of delay elements currently utilized in each of delay stages 142, 144, 146, 148, 150 is to be incremented, decremented or left constant in order to achieve the desired delay lock. In particular, phase comparator 152 provides an increment/decrement signal 153 to a delay control circuit 154. Based on increment/decrement signal 153, delay control circuit 154 controls the number of delay elements used by each of delay stages 142, 144, 146, 148, 150. In some cases, the same number of delay elements are utilized in each of delay stages 162, 164. In other cases, the number of delay elements that are utilized by delay stages 162, 164 is mathematically related to that determined by delay control circuit 154. In either case, the number of delay elements used in each of delay stages 142, 144, 146, 148, 150 to achieve a desired delay lock condition corresponds to the number of delay elements utilized in delay stages 162, 164.

As just one of many examples, delay lock loop circuit 120 may be configured such that it locks when the output of delay stage 150 is phase delayed three hundred and sixty degrees from reference clock 122. In such a case, the delay introduced by delay stages 162, 164 may be a time corresponding to the aforementioned ninety degree phase delay. Alternatively, the delay introduced by delay stages 162, 164 may be a multiple of or a division of the time corresponding to the aforementioned ninety degree phase delay. Such a multiple or division of the time may be accomplished, for example, by shifting a binary value representing the number of utilized delay elements either right or left. It should be noted that phase delays other than ninety degrees may be achieved using one or more embodiments of the present invention. For example, a delay lock loop circuit may be configured to yield a seventy-two degree phase delay. As yet another example, a delay unrelated to phase shift, but rather an absolute time may be achieved. Based on the disclosure provided herein, one of ordinary skill in the art will recognize various delays that may be implemented using one or more embodiments of the present invention.

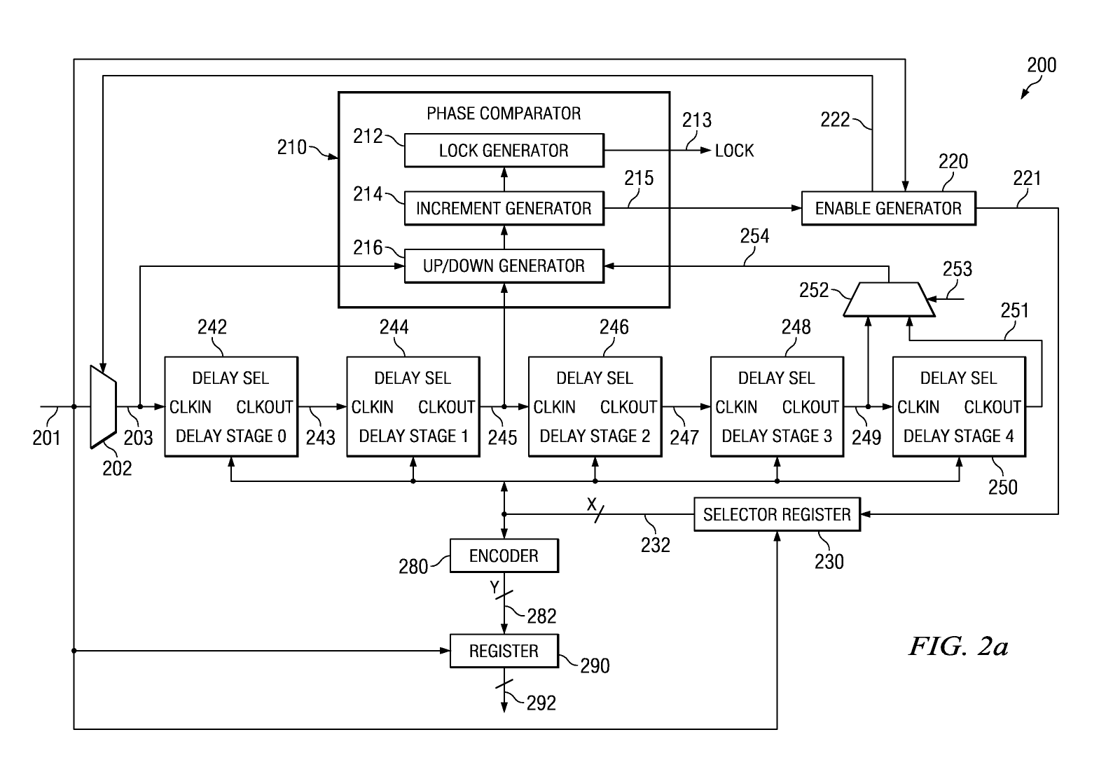

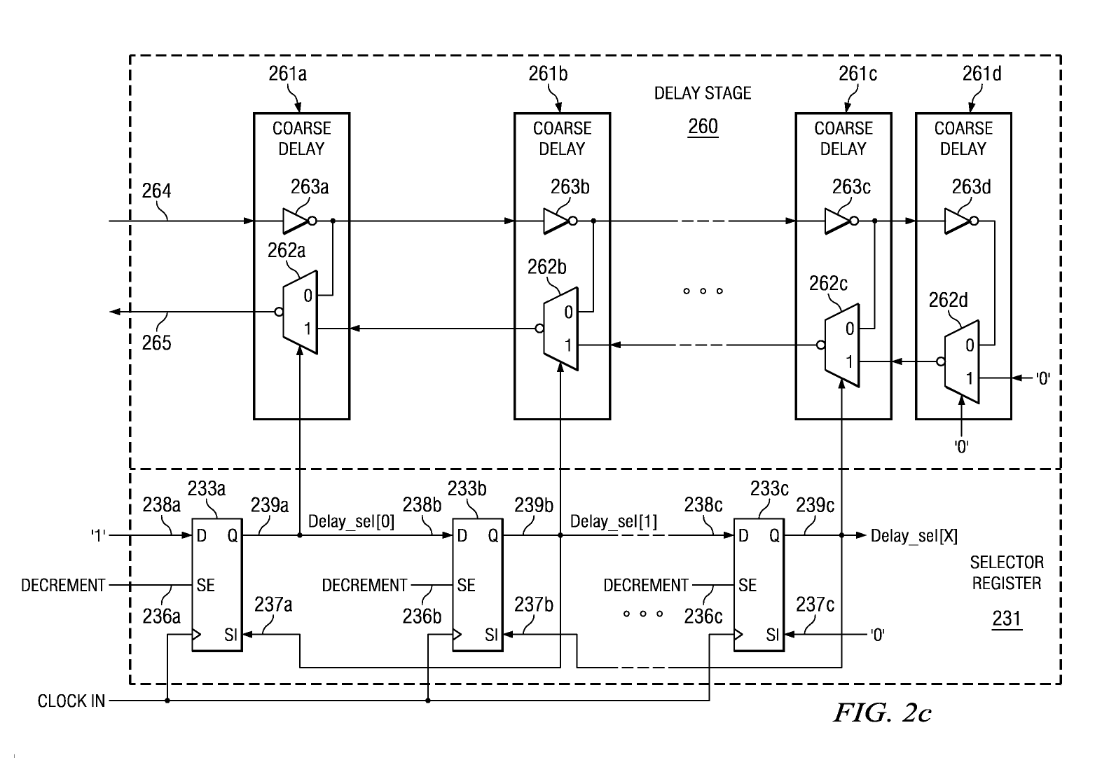

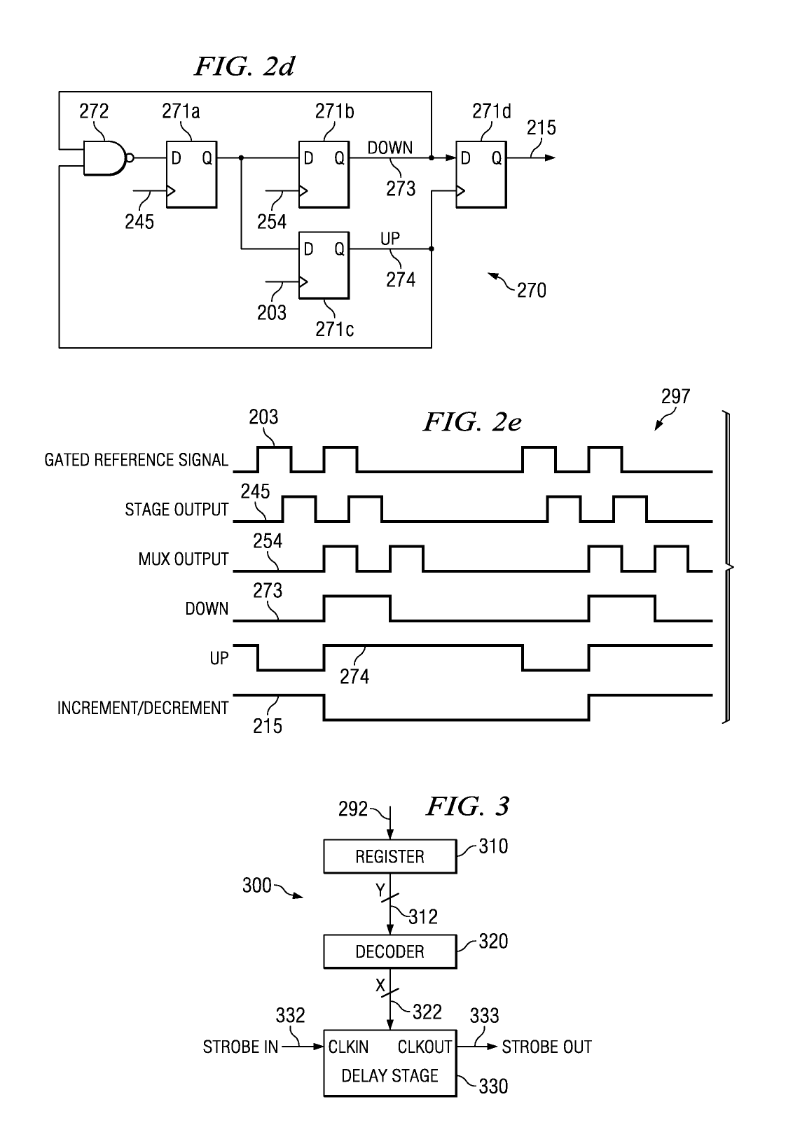

Turning to FIGS. 2a-2e, a delay lock loop circuit 200 including glitch reduction circuitry in accordance with some embodiments of the present invention is depicted. Delay lock loop circuit 200 includes a set of delay stages 242, 244, 246, 248, 250. Further, delay lock loop circuit 200 includes a feedback loop that includes a phase comparator 210, an enable generator 220, and a unified selector register 230. Delay lock loop circuit 200 also includes a reference signal gate 202, and a phase selector multiplexer 252. In one particular embodiment of the present invention, each of the aforementioned delay stages is designed to implement a phase delay of about seventy-two degrees. In such cases, phase selector multiplexer 252 provides an ability to select between a one stage seventy-two degree phase shift or a one stage ninety degree phase shift depending upon whether a selector input 253 is set such that phase selector multiplexer 252 causes stage output 249 or stage output 251 to drive a multiplexer output 254. Based on the disclosure provided herein, one of ordinary skill in the art will recognize a variety of embodiments that do not employ a multiplexer 252, or that employ additional multiplexers to allow for selection of different stage outputs.

Reference signal gate 202 receives a reference signal 201 and provides a gated reference signal 203. In one particular embodiment of the present invention includes an AND gate that ANDs an inverted version of gate control output 222 with reference signal 201. In some cases, circuitry is included that controls the timing of gate control output such that producing gated reference signal 203 from reference signal 201 does not result in glitches on gated reference signal 203. Based on the disclosure provided herein, one of ordinary skill in the art will recognized a variety of glitch free gating circuits that may be utilized in relation to the various embodiments of the present invention. Delay stage 242 receives gated reference signal 203, and provides a stage output 243. Stage output 243 is gated reference signal 203 delayed by a determined amount. Delay stage 244 receives stage output 243, and provides a stage output 245. Stage output 245 is stage output 243 delayed by a determined amount. Delay stage 246 receives stage output 245, and provides a stage output 247. Stage output 247 is stage output 245 delayed by a determined amount. Delay stage 248 receives stage output 247, and provides a stage output 249. Stage output 249 is stage output 247 delayed by a determined amount. Delay stage 250 receives stage output 249, and provides a stage output 251. Stage output 251 is stage output 249 delayed by a determined amount. Each of delay stages 242, 244, 246, 248, 250 includes a number of delay elements that may be selectably incorporated in a delay chain.

Gated reference signal 203, stage output 245, and one of stage output 249 or stage output 251 are provided to an up/down generator 216 of phase comparator 210. Up/down generator 216 provides an output to an increment generator 214 that indicates whether a number of delay elements used in each of delay stages 242, 244, 246, 248, 250 should be incremented, decremented or maintained constant to achieve the desired phase shift. Increment generator 214 provides an output to a lock generator 212 that provides a lock output 213.

In addition, increment generator 214 provides an increment/decrement signal 215 to an enable generator 220. Enable generator 220 controls the modification of a unified selector register 230 via a set of control signals 221. In one particular embodiment of the present invention, control signals 221 include an enable signal and an increment/decrement/no-change signal. In such a case when the increment/decrement/no-change signal indicates an increment and the enable signal is asserted, the value maintained in unified selector register 230 is incremented. Alternatively, when the increment/decrement/no-change signal indicates a decrement and the enable signal is asserted, the value maintained in unified selector register 230 is decremented. As another alternative, when the increment/decrement/no-change signal indicates a no-change, the value maintained in unified selector register 230 remains constant regardless of the state of the enable signal. In another particular embodiment of the present invention, control signals 221 include an enable signal and an increment/decrement signal. In such a case when the increment/decrement signal indicates an increment and the enable signal is asserted, the value maintained in unified selector register 230 is incremented. Alternatively, when the increment/decrement signal indicates a decrement and the enable signal is asserted, the value maintained in unified selector register 230 is decremented. In such an embodiment, an increment or decrement is always indicated as the circuit toggles around the lock condition.

In some embodiments of the present invention, enable generator 220 includes a counter circuit that is synchronized to reference signal 201. The counter circuit periodically asserts an enable signal (part of control signals 221). In one particular embodiment of the present invention, the counter circuit asserts the enable signal once for every four cycles of reference signal 201. In such a case, a gate control output 222 derived from the counter may be provided to reference signal gate 202 such that gated reference signal 203 does not assert when the enable of control signals 221 is asserted. In this way, glitches are avoided when the value in unified selector register 230 is updated. It should be noted that it may be desirable to increment toward a lock condition followed by a decrement where a step beyond the lock condition occurs. In this way, the possibility of locking to upper multiples of a desired phase shift is reduced.

An X-bit selector value 232 maintained in unified selector register 230 is provided to each of delay stages 242, 244, 246, 248, 250. In operation, X-bit selector value 232 selects the number of the delay elements in each of delay stages 242, 244, 246, 248, 250 that are used in a delay chain implemented by the respective delay stage. In one particular embodiment of the present invention, X-bit selector register is sixty-three bits wide, and the number of selectable delay elements in each of delay stages 242, 244, 246, 248, 250 is also sixty-three. It should be noted that the aforementioned delay width and register width is related to a particular implementation. It should also be noted that in contrast to the preceding example, the width of unified selector register 230 need not necessarily match the number of delay elements implemented in each of delay stages 242, 244, 246, 248, 250. Further, it should be noted that each of delay stages 242, 244, 246, 248, 250 do not necessarily need to include the same number of delay elements. Based on the disclosure provided herein, one of ordinary skill in the art will recognize a number of different delay widths and register widths that may be used in accordance with different embodiments of the present invention.

X-bit value 232 may be used to select a number of delay elements of one or more slave delay stages (not shown). In such cases, X-bit value 232 may be encoded using an encoder 280 that yields an encoded Y-bit value 282. This may be used to limit the width of an output bus used to transfer X-bit value 232 to the slave delay stages. Encoded Y-bit value 282 may be registered using a register 290, and a register output 292 is provided to the associated slave delay stages. Based on the disclosure provided herein, one of ordinary skill in the art will recognize a variety of other circuits that may be used to transfer X-bit value 232 to slave delay stages depending upon particular design constraints.

Operation of delay lock loop circuit 200 is described in relation to a timing diagram 295 of FIG. 2b. Turning to FIG. 2b, reference signal 201 is shown as a repeating clock with approximately a fifty percent duty cycle. As shown, enable generator 220 asserts gate control output 222 once every four cycles of reference signal 201. Reference signal gate 202 gates reference signal 201 with gate control output 222 to produce gated reference signal 203. In this example, gate control output 222 and the enable that is part of signals 221 have the same characteristics. In particular, gated reference signal 203 is reference signal 201 that is not asserted whenever gate control output 222 is asserted.

Whenever the value in unified selector register 230 is to be incremented, increment generator 214 asserts increment/decrement signal 215 to indicate an increment operation (e.g., a logic ‘1’ in this example). Alternatively, whenever the value in unified selector register 230 is to be decremented, increment generator 214 asserts increment/decrement signal 215 to indicate a decrement operation (e.g., a logic ‘0’ in this example). Increment/decrement signal 215 is re-clocked by enable generator 220 as increment signal (part of signals 221). Signals 221 are passed by enable generator 220 to unified selector register 230 where they cause either an increment, decrement, or no change of X-bit value 232 upon the next positive edge of reference signal 201. As previously stated, X-bit value 232 causes a change in the number of delay elements utilized in delay stages 242, 244, 246, 248, 250 (i.e., a change in the delay incurred through each of the respective delay stages).

Turning to FIG. 2c, a detailed schematic of one implementation of a delay stage 260 and a selector register 231 is shown. Delay stage 260 may be used in place of any or all of delay stages 242, 244, 246, 248, 250 discussed above in relation to FIG. 2a. Similarly, selector register 231 may be used in place of selector register 232 discussed above in relation to FIG. 2a. As shown, delay stage 260 includes a number of delay elements 261 that can be configured as a chain of delay elements including one delay element up to the total number of delay elements depending upon the value maintained in selector register 231. Delay stage 260 receives an input signal 264 and provides an output signal 265. As an example, where delay stage 260 is used in place of delay stage 242, input signal 264 corresponds to gated reference signal 203 and output signal 265 corresponds to stage output 243. Similarly, outputs from selector register 231 correspond to X-bit value 232.

Each delay element 261 includes a delay buffer 263 that may be, but is not limited to an inverting buffer, a logic gate, or a non-inverting buffer. Based on the disclosure provided herein, one of ordinary skill in the art will recognize a variety of circuits that may be used to cause a signal delay. In addition, each delay element 261 includes a multiplexer 262 that is controlled by an input from selector register 231 and is used to control whether the signal is turned around at the particular delay element in delay stage 260. In particular, when the value provided from selector register 231 is a logic ‘1’, the signal will not turn around, and in turn will select the signal from the next delay element. In contrast, when the value provided from selector register 231 is a logic ‘0’, the signal turns around at that delay element. As each delay element 261 drives a subsequent delay element 261 (i.e., the output of delay element 261d, drives the output of delay element 261c), the value provided from selector register 231 includes a series of logic ‘1’s followed by a series of logic ‘0’s, with the transition between logic ‘0’s and logic ‘1’s being positioned such that it corresponds to the overall delay line length implemented in delay stage 260.

Selector register 231 is implemented as a shift register that causes a series of logic ‘1’s followed by a series of logic ‘0’s to shift right whenever the delay implemented by delay stage 261 is to be increased, and to shift left whenever the delay implemented by delay stage 261 is to be decreased. In particular, selector register 231 includes a number of flip-flops 233 configured in series. Each of flip-flops 233 includes a shift enable input 236, a scan input 237, a data input 238 and an output 239. In operation, when a shift right is to occur, an increment signal input (e.g., part of signals 221) is asserted high, and upon the next assertion of a clock input (e.g., reference input 201) the block of logic ‘1’s followed by the block of logic ‘0’s shifts right. In contrast, when a shift left is to occur, the increment signal input (e.g., part of signals 221) is asserted low, and upon the next assertion of a clock input (e.g., reference input 201) the block of logic ‘1’s followed by the block of logic ‘0’s shifts left. In some cases, an additional enable signal may be added to each of flip-flops 233 that enables both right and left shifting. Based on the disclosure provided herein, one of ordinary skill in the art will recognize other designs for implementing selector register 231.

Turning to FIG. 2d, an exemplary up/down and increment generator circuit 270 that may be used in relation to one or more embodiments of the present invention is depicted. Up/down and increment generator circuit 270 may be used in place of up/down generator 216 and increment generator 214 discussed above in relation to FIG. 2a. Up/down and increment generator circuit 270 includes a number of flip-flops 271 that are each clocked using different outputs and inputs from delay stages 242, 244, 246, 248, 250. In particular, a flip-flop 271a is clocked by stage output 245, a flip-flop 271b is clocked by multiplexer output 254 that is either stage output 249 or stage output 251, and a flip-flop 271c is clocked by gated reference signal 203. A flip-flop 271d is clocked by the output of flip-flop 271c. The data input of both flip-flop 271b and flip-flop 271c are connected to the output of flip-flop 271a. The output of flip-flop 271b (i.e., a down signal 273) and the output of flip-flop 271c (i.e., an up signal 274) are applied as inputs to a NAND gate 272, and the output of NAND gate 272 is applied to the input of flip-flop 271a. The output of flip-flop 271b is also applied to the input of flip-flop 271d. The output of flip-flop 271d is increment/decrement signal 215.

Operation of up/down and increment generator circuit 270 is described in relation to a timing diagram 297 of FIG. 2e. As shown, gated reference signal 203 is a gated version of a cock signal with two out of every four clock cycles gated out by reference signal gate 202. Gated reference signal 203 is passed through delay stage 242 and delay stage 244 to create stage output 245. Multiplexer output 254 is gated reference signal 203 after it has been passed through delay stage 242, delay stage 244, delay stage 246, delay stage 248 and in some cases delay stage 250 depending upon the assertion of selector input as discussed above in relation to FIG. 2a. As shown, up signal 274 and down signal 273 are originally asserted at a logic ‘0’. Upon the next positive transition of stage output 245, the output of flip-flop 271a transitions to a logic ‘1’. Then, upon the next positive transition of gated reference clock 203, up signal 274 transitions to a logic ‘1’, and upon the next positive transition of multiplexer output 254, down signal 273 transitions to a logic ‘1’. Where up signal 274 transitions before down signal 273, increment/decrement signal 215 is asserted as a logic ‘0’. In contrast, where up signal 274 transitions after down signal 273, increment/decrement signal 215 is asserted as a logic ‘1’. In this way, a signal indicating whether the value in unified selector register 230 may be incremented or decremented based on a comparison of a phase shifted version of a reference clock with the reference clock. It should be noted that up/down and increment generator circuit 270 is merely exemplary, and that one of ordinary skill in the art will recognize other up/down circuits that may be used in relation to various embodiments of the present invention.

Turning to FIG. 3, a slave delay stage 330 along with an interface circuit 300 that may be implemented in relation to various embodiments of the present invention is depicted. Interface circuit 300 includes a register 310 that registers register output 292 from delay lock loop 200 depicted in FIG. 2a. A Y-bit output 312 from register 310 is passed through decoder 320 that decodes it to create an X-bit output 322. In some cases, X-bit output 322 is the same as X-bit output 232 discussed above. X-bit output 322 is applied to delay stage 330 where it is used to select the number of delay elements that are utilized in delay stage 330 to strobe in 332 to create strobe 333. In some cases, delay stage 330 is identical to delay stages 242, 244, 246, 248, 250. In other cases, delay stage 330 includes fewer or more delay elements than that included in delay stages 242, 244, 246, 248, 250 and applying X-bit output 322 may cause the selection of a predictable, but different delay than that produced by delay stages 242, 244, 246, 248, 250. For example, delay stage 330 may include twice as many delay elements and each bit of X-bit output 322 may correspond to two delay elements making the delay produced by delay stage 330 twice that of any of delay stages 242, 244, 246, 248, 250. Based on the disclosure provided herein, one of ordinary skill in the art will appreciate various designs that may be employed to generate a delay in delay stage 330 relative to the corresponding delay in delay stages 242, 244, 246, 248, 250.

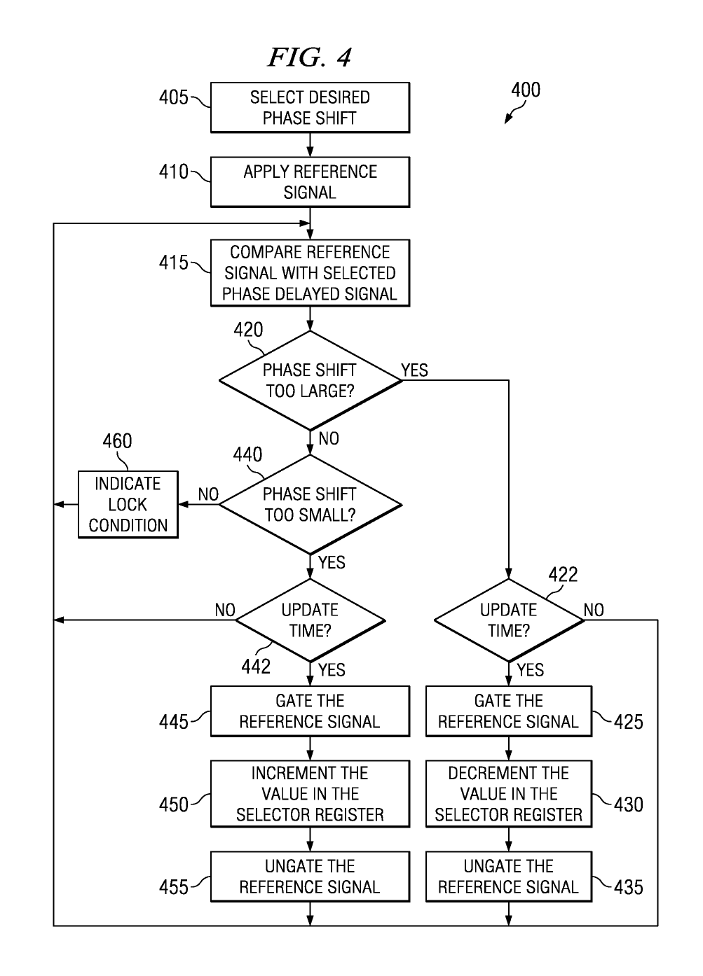

Turning to FIG. 4, a flow diagram 400 shows a method in accordance with one or more embodiments of the present invention for glitch free update of a delay lock loop circuit. At the outset, it should be noted that the flow diagram shows a serial operation, but it should be noted that some of the processes represented are ongoing in parallel to one or more of the other processes. Thus, for example, a comparison circuit may be continually updating a comparison result while the effect of a previous comparison result is still being processed. Based on the disclosure provided herein, one of ordinary skill in the art will recognize a variety of potentially parallel processes that may be ongoing relative to a related serial process.

Following flow diagram 400, a desired phase shift is selected (block 405). This may include, for example, asserting selector input 253 to select between either comparison with stage output 249 or with stage output 251. In addition, a reference signal is applied to the input of a chain of delay stages (block 410). The applied reference signal may be, for example, reference signal 201. The applied reference signal may be a clock signal that repeats with a predictable cycle, or any other type of signal suitable for delay locking. The applied reference signal is compared with the selected phase delayed signal (block 415). This may include, but is not limited to, comparing one or more outputs of delay stages 242, 244, 246, 248, 250 with the reference signal.

Based on the comparison of the reference signal with the selected phase delayed signal (block 415), it is determined whether the phase delay introduced by the circuit us approximately the desired delay (blocks 420, 440). Where a phase shift that has been introduced is too large (block 420), it is determined if an update of the selector register is desired based on a timer or counter output (block 422). Where it is not time to update the selector register (block 422), no update is completed. Alternatively, where it is time to update the selector register (block 422), the reference signal is gated (block 425). While the reference signal is gated (block 425), the value in the selector register is modified to cause a reduction in the number of delay elements used in the delay stages of the circuit (block 430). Reducing the number of delay elements causes a reduction in the amount of delay introduced by each of the delay stages. In some cases, the selector register is a shift register, and reducing the number of included delay elements includes shifting a block of logic ‘1’s followed by a block of logic ‘0’s such that fewer delay elements are utilized. Once the selector register has been updated (block 430), the reference signal is ungated (i.e., the previous gating of the reference signal is removed) (block 435). Once this is complete, the process of comparing the reference signal with the phase delayed signal is repeated (block 415). By gating the reference signal during an update of the selector register, glitching at the output of delay stages due to modification of the number of delay elements used in the delay stages is reduced or eliminated.

Alternatively, where an introduced phase shift is less than desired (block 440), it is determined if an update of the selector register is desired based on a timer or counter output (block 442). Where it is not time to update the selector register (block 422), no update is completed. Alternatively, where it is time to update the selector register (block 442), the reference signal is gated (block 445). While the reference signal is gated (block 445), the value in the selector register is modified to cause an increase in the number of delay elements used in the delay stages of the circuit (block 450). Increasing the number of delay elements causes an increase in the amount of delay introduced by each of the delay stages. In some cases, the selector register is a shift register, and increasing the number of included delay elements includes shifting a block of logic ‘1’s followed by a block of logic ‘0’s such that more delay elements are utilized. Once the selector register has been updated (block 450), the reference signal is ungated (i.e., the previous gating of the reference signal is removed) (block 455). Once this is complete, the process of comparing the reference signal with the phase delayed signal is repeated (block 415). Again, by gating the reference signal during an update of the selector register, glitching at the output of delay stages due to modification of the number of delay elements used in the delay stages is reduced or eliminated. Where the phase shift is at a desirable point (i.e., neither too large (block 420) nor too small (block 440)), a lock condition is indicated. It should be noted that in some embodiments of the present invention the comparison and update process continues even after a lock condition occurs.

In conclusion, the present invention provides novel systems, devices, methods for signal synchronization. While detailed descriptions of one or more embodiments of the invention have been given above, various alternatives, modifications, and equivalents will be apparent to those skilled in the art without varying from the spirit of the invention. For example, while a DLL is described as being used in relation to a memory system, such a DLL could be used in relation with other systems. Therefore, the above description should not be taken as limiting the scope of the invention, which is defined by the appended claims.

What is claimed is:

1. A delay lock loop circuit, the circuit comprising:
a reference signal;
at least a first delay stage and a second delay stage, wherein each of the first delay stage and the second delay stage includes a plurality of selectable delay elements, wherein a gated reference signal drives an input of the first delay stage, wherein the first delay stage provides a first output, wherein the first output drives an input of the second delay stage, and wherein the second delay stage provides a second output;
a unified selector register associated with both the first delay stage and the second delay stage, wherein a value maintained in the unified selector register determines a number of the selectable delay elements utilized in the first delay stage and a number of the selectable delay elements utilized in the second delay stage, wherein modification of the value maintained in the unified selector register is synchronized to the reference signal; and
a reference signal gate, wherein the reference signal gate receives the reference signal and provides the gated reference signal, and wherein the gated reference signal is substantially the reference signal modified such that the gated reference signal is not asserted when modification of the unified selector register is enabled.

2. The circuit of claim 1, wherein the circuit further comprises:
a counter circuit, wherein the counter circuit is synchronized to the reference signal, and wherein the counter circuit periodically asserts an enable signal, and wherein the enable signal enables modification of the unified selector register.

3. The circuit of claim 2, wherein the reference signal gate gates the reference signal whenever the enable signal is asserted.

4. The circuit of claim 1, wherein the circuit further comprises:
a third delay stage, a fourth delay stage and a fifth delay stage, wherein each of the third delay stage, the fourth delay stage and the fifth delay stage includes the plurality of selectable delay elements, wherein the second output drives an input of the third delay stage, wherein the third delay stage provides a third output, wherein the third output drives an input of the fourth delay stage, wherein the fourth delay stage provides a fourth output, wherein the fourth output drives an input of the fifth delay stage, and wherein the fifth delay stage provides a fifth output; and
wherein the unified selector register is additionally associated with each of the third delay stage, the fourth delay stage and the fifth delay stage, and wherein the value maintained in the unified selector register determines a number of the selectable delay elements utilized in the third delay stage, a number of the selectable delay elements utilized in the fourth delay stage, and the number of the selectable delay elements utilized in the fifth delay stage.

5. The circuit of claim 4, wherein the circuit further comprises:
a counter circuit, wherein the counter circuit is synchronized to the reference signal, and wherein the counter circuit periodically asserts an enable signal, and wherein the enable signal enables modification of the unified selector register.

6. The circuit of claim 5, wherein the reference signal gate gates the reference signal whenever the enable signal is asserted.

7. The circuit of claim 4, wherein the circuit further comprises:
a feedback loop, wherein at least two of the reference signal, the gated reference signal, the first output, the second output, the third output, the fourth output and the fifth output are provided as inputs to the feedback loop; and wherein the feedback loop is operable to determine the value maintained in the unified selector register.

8. The circuit of claim 7, wherein the feedback loop includes an increment/decrement circuit, and wherein the increment/decrement circuit is operable to modify the value in the unified selection register based on a comparison of the gated reference signal with the at least one of the first output, the second output, the third output, the fourth output and the fifth output.

9. The circuit of claim 1, wherein the first delay stage and the second delay stage are substantially identical.

10. The circuit of claim 1, wherein the plurality of delay elements is selected from a group consisting of: a plurality of single input buffers, and a plurality of multiple input logic gates.

11. A method for glitch reduction in a delay lock loop circuit, the method comprising:
receiving a reference signal;
providing a delay lock loop circuit, wherein the delay lock loop circuit includes at least a first delay stage and a second delay stage, wherein each of the first delay stage and the second delay stage includes a plurality of selectable delay elements, wherein a gated reference signal drives an input of the first delay stage, wherein the first delay stage provides a first output, wherein the first output drives an input of the second delay stage, wherein the second delay stage provides a second output, a unified selector register associated with both the first delay stage and the second delay stage, and wherein a value maintained in the unified selector register determines a number of the selectable delay elements utilized in the first delay stage and a number of the selectable delay elements utilized in the second delay stage;
periodically asserting an enable signal, wherein the enable signal enables modification of the unified selector register;
modifying the value maintained in the unified selector register, wherein the number of the selectable delay elements utilized in the first delay stage and the number of the selectable delay elements utilized in the second delay stage are modified; and
gating the reference signal whenever the enable signal is asserted to produce the gated reference signal.

12. The method of claim 11, wherein the delay lock loop circuit further includes:
a third delay stage, a fourth delay stage and a fifth delay stage, wherein each of the third delay stage, the fourth delay stage and the fifth delay stage includes the plurality of selectable delay elements, wherein the second output drives an input of the third delay stage, wherein the third delay stage provides a third output, wherein the third output drives an input of the fourth delay stage, wherein the fourth delay stage provides a fourth output, wherein the fourth output drives an input of the fifth delay stage, wherein the fifth delay stage provides a fifth output, wherein the unified selector register is additionally associated with each of the third delay stage, the fourth delay stage and the fifth delay stage, and wherein the value maintained in the unified selector register determines a number of the selectable delay elements utilized in the third delay stage, a number of the selectable delay elements utilized in the fourth delay stage, and the number of the selectable delay elements utilized in the fifth delay stage.

13. The method of claim 12, wherein the delay lock loop circuit further includes:
a feedback loop, wherein the at least two of the reference signal, the gated reference signal, the first output, the second output, the third output, the fourth output and the fifth output are provided as inputs to the feedback loop; and wherein the feedback loop is operable to determine the value maintained in the unified selector register.

14. The method of claim 13, wherein the feedback loop includes an increment/decrement circuit, and wherein the increment/decrement circuit is operable to modify the value in the unified selection register based on a comparison of the gated reference signal with the at least one of the first output, the second output, the third output, the fourth output and the fifth output.

15. The method of claim 11, wherein periodically asserting an enable signal is governed by an output from a counter that is synchronized to the reference signal.

16. The method of claim 11, wherein the first delay stage and the second delay stage are substantially identical.

17. The method of claim 11, wherein the plurality of delay elements is selected from a group consisting of: a plurality of single input buffers, and a plurality of multiple input logic gates.

18. A delay lock loop circuit, the circuit comprising:
a reference signal;
at least a first delay stage, a second delay stage, a third delay stage and a fourth delay stage, wherein each of the first delay stage, the second delay stage, the third delay stage and the fourth delay stage includes a plurality of selectable delay elements, wherein a gated reference signal drives an input of the first delay stage, wherein the first delay stage provides a first output, wherein the first output drives an input of the second delay stage, wherein the second delay stage provides a second output, wherein the second output drives an input of the third delay stage, and wherein the third delay stage provides a third output, wherein the third output drives an input of the fourth delay stage, and wherein the fourth delay stage provides a fourth output;
a unified selector register associated with all of the first delay stage, the second delay stage, the third delay stage and the fourth delay stage, wherein a value maintained in the unified selector register determines a number of the selectable delay elements utilized in the first delay stage, a number of the selectable delay elements utilized in the second delay stage, a number of the selectable delay elements utilized in the third delay stage, and a number of the selectable delay elements utilized in the fourth delay stage, and wherein modification of the value maintained in the unified selector register is synchronized to the reference signal; and
a reference signal gate, wherein the reference signal gate receives the reference signal and provides the gated reference signal, and wherein the gated reference signal is substantially the reference signal modified such that the gated reference signal is not asserted when modification of the unified selector register is enabled.

19. The circuit of claim 18, wherein the circuit further comprises:
a counter circuit, wherein the counter circuit is synchronized to the reference signal, and wherein the counter circuit periodically asserts an enable signal, wherein the enable signal enables modification of the unified selector register, and wherein the reference signal gate gates the reference signal whenever the enable signal is asserted.

20. The circuit of claim 18, wherein the circuit further comprises:
a feedback loop, wherein the gated reference signal and the fourth output are provided as inputs to the feedback loop, wherein the feedback loop includes an increment/decrement circuit, and wherein the increment/decrement circuit is operable to modify the value in the unified selection register based on a comparison of the gated reference signal and the fourth output.
